(19) United States
(12) Patent Application Publication
(10) Pub. No.: US 2025/0211184 A1
(43) Pub. Date: Jun. 26, 2025

(54) HIGH SPEED RECEIVER CIRCUITRY

(71) Applicant: Western Digital Technologies, Inc., San Jose, CA (US)

(72) Inventors: Mohammad Mahmoodi, Santa Barbara, CA (US); Zahra Fahimi, Santa Barbara, CA (US); Martin Lueker-Boden, Fremont, CA (US)

(73) Assignee: Western Digital Technologies, Inc., San Jose, CA (US)

(21) Appl. No.: 18/390,996

(22) Filed: Dec. 20, 2023

(51) Int. Cl. H03F 3/45; H03K 3/037

(52) U.S. Cl. CPC H03F 3/45269; H03K 3/037; H03F 2200/129

(57) ABSTRACT

Technology for high speed receiver circuitry. The receiver has multiple stages. The gain of a first stage may be relatively low, but is sufficient to increase the signal swing to a target minimum even if there is a relatively small input signal swing. Additional stages provide further gain. The final stage will provide a fully rail-to-rail signal for a wide range of input signal swings. The initial stage may be a fully differential amplifier with a passive load. In an aspect, resistor-based bias circuitry compensates for process and/or temperature variations in the fully differential amplifier. In an aspect, inverter-based bias circuitry provides a bias for a stage having an active load to compensate for process and/or temperature variations in the active load.

### BACKGROUND

This disclosure pertains to communication interfaces. FIG. 1 depicts a conventional communication system having a transmitter (Tx) 102, channel 104, and receiver (Rx) 106. The transmitter 102 and the receiver 106 may be integrated circuits (IC). In general, an integrated circuit (IC)—also referred to as a monolithic IC, a chip, or a microchip—is an assembly or a collection of electric circuit components (including active components, such as transistors and diodes, and passive components, such as capacitors and resistors) and their interconnections formed as a single unit, such as by being fabricated, on a substrate typically made of a semiconductor material such as silicon. The transmitting circuit 102 and the receiving circuit 106 are separate integrated circuits, and the channel 104 (or communication bus) is configured to communicate signals external to the separate transmitting circuit (IC) 102 and the receiving circuit (IC) 106.

The transmitter 102 has a driver, which has resistors R_{PU} and R_{PD}. The receiver 106 has a termination resistance (Rterm) 108, internal resistance (Resd) 110, and receiving circuitry 112. The receiving circuitry 112 compares the signal at node A with a reference voltage Vref. The receiver 112 also amplifies the difference between the signal at node A with a reference voltage Vref. In this example, the transmitter 102 sends a single-ended signal and the receiving circuitry 112 is a single-ended receiver.

In many high-speed mixed-signal interface circuits (e.g., DRAM), the input swing to the receiver 106 depends on the termination 108 and driver resistances. In practice, these resistances are often optimized to achieve minimum reflections on the transmitter and receiver sides. For example, a Tx driver could be configured as 34Ω or 48Ω. The receiver termination 108 could vary from, for example, 40Ω to 480Ω. Hence, the input swing of the receiver may vary significantly from ˜50 mV to 500 mV. This would make the Rx design quite challenging for both single-ended and differential pins.

FIG. 2 shows further details of the possible input swing of the receiver 106. FIG. 2 shows example signals at the input of the receiver Rx, labeled as node A in FIG. 1. FIG. 2 shows an example of a small signal swing 202 and a large signal swing 204. An ideal reference level (Vref,SS) 206 is depicted for the small signal swing and an ideal reference level (Vref,LS) 208 is depicted for the large signal swing. Each signal has a high voltage (Data=1) of Vdd. The low voltage (Data=0) is given by Equation 1.

$$\frac{{R}_{PD}}{{R}_{PD} + {R}_{Term}} VDD \qquad Eq . 1$$

FIG. 3 is a schematic diagram of a conventional single-ended receiver 300 having a resistive load (RL). To accommodate for the large range of signal swing, Vref can be supplied by an internal DAC. Therefore, the value of Vref could range from, for example, 0.38 V to 1.07V to accommodate signal swings. The conventional design has good power supply rejection ratio (PSRR), especially for a low signal swing. However, the gain and output common mode (CM) are highly process dependent, which results in issues for a highly variable input signal swing. Temperature variations also negatively impact receiver performance.

Differential receivers, which process differential signals, also face similar issues as those just discussed for processing single-ended signals. In a system using differential communication there are two channels with the transmitter sending, for example, a signal and a compliment of the signal. The receiving chip has on chip termination resistors for each channel. The differential receiver may thus compare data with data_bar and amplify that difference. Large differences in signal swing at the differential receiver may also impact differential receivers. Process and/or temperature variations also negatively impact differential receiver performance. Therefore, variations in the input signal swing present challenges in properly identifying the data in the data signals. For example, the variations make it difficult to achieve a wide data valid window. The ever increasing communication bus speeds mean that such variations have a greater impact on achieving a wide data valid window. Moreover, process and/or temperature variations negatively impact receivers.

### BRIEF DESCRIPTION OF THE DRAWINGS

Like-numbered elements refer to common components in the different Figures.

FIG. 1 depicts a conventional communication system having a transmitter and receiver.

FIG. 2 shows details of the possible input swing of the receiver in FIG. 1.

FIG. 3 is a schematic diagram of a conventional single-ended receiver having a resistive load.

FIG. 4 is a block diagram of a receiver circuitry in which embodiments of receivers disclosed herein may be practiced.

FIG. 5 depicts a block diagram of one embodiment of stages in a receiver.

FIG. 6 depicts a block diagram of another embodiment of stages in a receiver.

FIG. 7 depicts a block diagram of another embodiment of stages in a receiver.

FIG. 8A is a high level diagram of a single-ended receiver.

FIG. 8B is a block diagram of components of one embodiment of a multi-mode single-ended receiver.

FIG. 9 is a schematic diagram of one embodiment of a receiver.

FIG. 10 is a schematic diagram of one embodiment of CMOS circuitry.

FIG. 11A is a graph of voltage waveforms versus time for the channel and various nodes in an embodiment of a receiver.

FIG. 11B is a DC voltage for a small swing example in an embodiment of a receiver.

FIG. 12A is another graph of voltage waveforms versus time for the channel and various nodes in an embodiment of a receiver.

FIG. 12B is a DC voltage the corresponds to the graph in FIG. 12A for a large swing example.

FIG. 13 is a high level diagram of a fully differential receiver.

FIG. 14 is a schematic diagram of one embodiment of a fully differential amplifier stage.

FIG. 15 is a schematic diagram of circuitry that may be used in combination with the stage depicted in FIG. 14.

FIG. 16 is a schematic diagram of one embodiment of a biasing circuit for an embodiment of a fully differential stage.

FIG. 17 is a schematic diagram of one embodiment of a biasing circuit for an embodiment of a differential input/single-ended output stage.

FIG. 18 is a high level schematic of a single-ended receiver.

FIG. 19 is a schematic diagram of one embodiment of a differential input/differential output amplifier stage.

FIGS. 20A-20F depict waveforms of voltage signals at various points in an embodiment of a differential receiver such as a receiver having a fully differential amplifier stage and the circuitry depicted in FIG. 15.

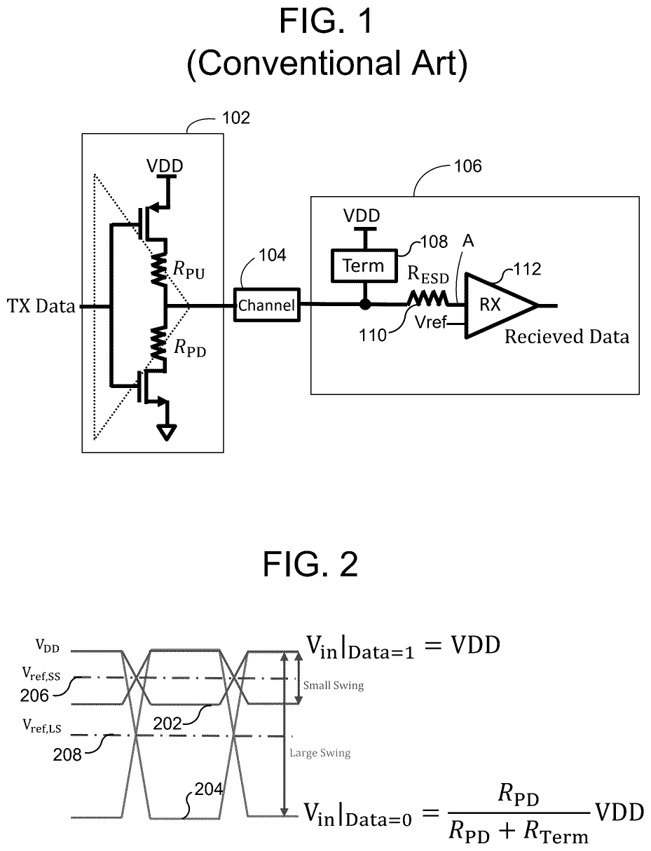

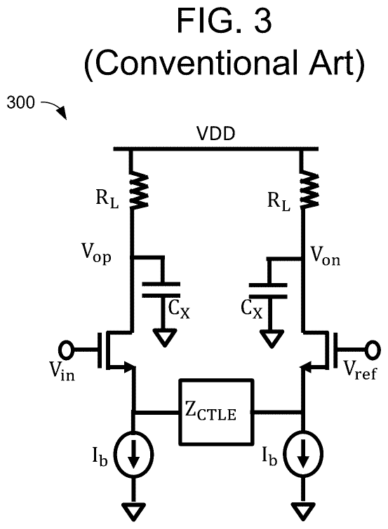

### DETAILED DESCRIPTION

Technology is disclosed herein for high speed receiver circuitry. Embodiments of high speed receiver circuitry disclosed herein are suitable for use in pseudo open drain (POD) architectures. Embodiments of the receiver circuitry accommodate a wide range of input signal swings. An embodiment of a receiver circuitry that processes differential signals produces an output signal with close to 50% duty cycle.

An embodiment of a receiver has multiple stages. The gain of a first stage is relatively low, but is sufficient to increase the signal swing to a target minimum even if there is a relatively small input signal swing. Additional stages provide further gain. The final stage will provide a fully rail-to-rail signal for a wide range of input signal swings.

In an embodiment, the initial stage is a fully differential amplifier with a passive load. Process and/or temperature variations could potentially impact performance of the fully differential amplifier. The common mode voltage at the differential output of the fully differential amplifier depends on a bias current and a resistance of the passive load. An embodiment includes resistor based bias circuitry that generates a bias current for the fully differential amplifier that has a magnitude that depends inversely on a resistance in the bias circuitry. Global process variations will impact the resistor in the passive load in a similar manner as the resistor in the bias circuitry. Moreover, temperature variations will impact the resistor in the passive load in a similar manner as the resistor in the bias circuitry. Therefore, the bias current mitigates process and/or temperature variations that may impact the fully differential amplifier. Consequently the common mode voltage at the differential output is made resistant to global process and/or temperature variations.

In an embodiment, a stage that receives the output of the fully differential amplifier is a differential input/single-ended output amplifier. This amplifier may have an active load. Process and/or temperature variations impact the transistors in the active load, which impact the common mode voltage at the single-ended output. An embodiment includes bias circuitry that generates a bias current for the stage with the active load that mitigates process and/or temperature variations in transistors in the active load, thereby keeping the common mode voltage at the single-ended output close to a target. In an embodiment, the single-ended output is connected to a stage having a CMOS inverter. An embodiment includes inverter based bias circuitry having an inverter that is a replica of the CMOS inverter. The bias current generated by this inverter-based bias circuitry ensures that the DC voltage at the single-ended output tracks the midpoint voltage of the voltage transfer curve (VTC) of the CMOS inverter in the stage connected to the stage with the active load.

An embodiment includes a differential receiver circuit having a fully differential amplifier whose outputs are connected to two complementary paths. Each path has circuitry that amplifies a difference between the two signals (Sig_c, Sig_t) of the differential output of the fully differential amplifier. However, one path amplifies Sig_c−Sig_t and the other path amplifies Sig_t−Sig_c. Each path produces a single-ended output signal that are compliments of each other (Sig_Out, Sig_Out_Bar) with the final differential output signal being the difference between the single-ended output signals (Sig_Out−Sig_Out_Bar).

In an embodiment the duty cycle of the differential output signal is improved by a latch connected between circuitry in the two paths. The latch improves the duty cycle by averaging a duty cycle of the signal in the first path with a duty cycle of the compliment signal in the second path. These and other technical benefits of embodiments of a receiver are described herein.

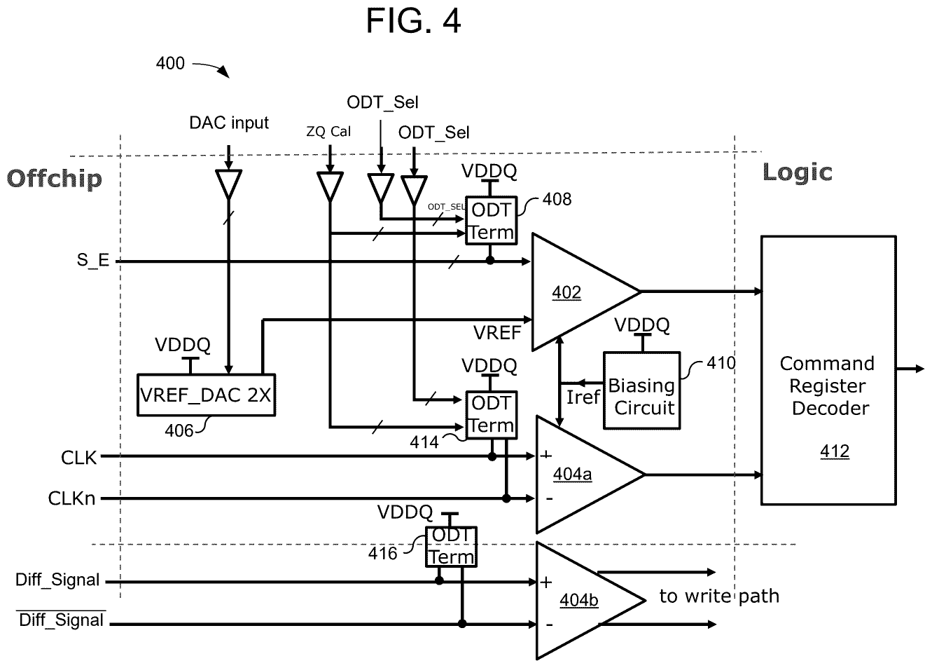

FIG. 4 is a block diagram of a receiver circuitry in which embodiments of receivers disclosed herein may be practiced. As one example, receiver circuitry in FIG. 4 could be used for communication in a system having DRAM. However, note that embodiments of receivers disclosed herein are not limited to DRAM. The receiver circuitry 400 has a single-ended receiver 402 and two differential receivers 404a, 404b. The single-ended receiver 402 inputs a single-ended signal (S_E) and a reference signal (Vref). The reference signal (Vref) is generated by an on-chip DAC 406. Note that for simplicity only one line is depicted for the single-ended signal (S_E), there may be many lines of single-ended signals. In a DRAM example, the single-ended signals could be provided on 14 CA pins and a CS pin. However, the receiver circuitry in FIG. 4 is not limited to DRAM. A first on die termination (ODT) 408 is connected to the single-ended receiver 402. A biasing circuit 410 provides a reference current (Iref) to the single-ended receiver 402. The single-ended receiver 402 is connected to the command register decoder 412. First differential receiver 404a receives a differential signal, which in this example is CLK and CLKn. First differential receiver 404a is connected to second ODT 414, which provide on-die termination resistance for the first differential receiver 404a. The first differential receiver 404a is connected to the command register decoder 412. The second differential receiver 404b receives a differential signal (Diff_Signal, Diff_Signal_Bar). Second differential receiver 404b is connected to third ODT 416, which provide on-die termination resistance for the second differential receiver 404b. The second differential receiver 404b is connected to the write path.

In some cases the receiver will process a data signal. A data signal is a signal that carries and/or includes data. The data carried by and/or included in a data signal includes a sequence of bits, where each bit includes or has a single-bit logic value of “1” or “0”. The data signal may include a series or sequence of data pulses corresponding to a bit sequence of the data. Each data pulse may be at a level that indicates a data value, otherwise referred to as a logic level or a logic value.

In some embodiments, the receivers disclosed herein are used with memory systems. A wide variety of memory technologies may be used in the memory system. Example memory technologies include DRAM, ReRAM memories (resistive random access memories), magnetoresistive memory (e.g., MRAM, Spin Transfer Torque MRAM, Spin Orbit Torque MRAM), FeRAM, phase change memory (e.g., PCM), NAND, and NOR.

One example of a ReRAM, or PCMRAM, cross point memory includes reversible resistance-switching elements arranged in cross point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. A storage device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a Ge₂Sb₂Te₅ alloy to achieve phase changes by electrically heating the phase change material. The doses of programming are electrical pulses of different amplitude and/or length resulting in different resistance values of the phase change material.

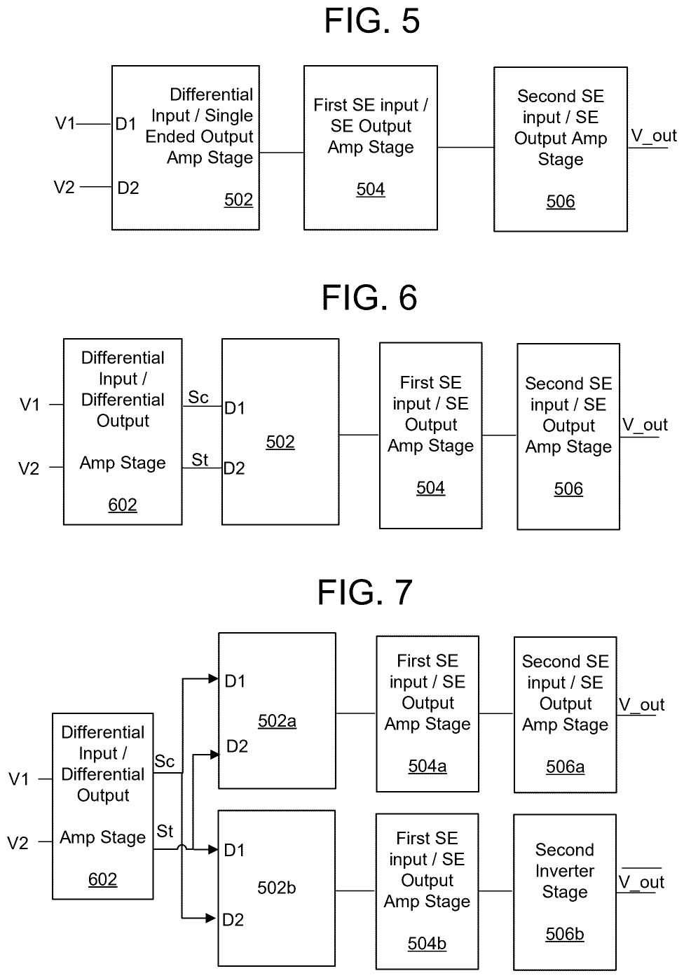

In some embodiments, the single-ended receiver 402 has multiple stages. In some embodiments, the differential receivers 404a, 404b each have multiple stages. FIG. 5 depicts a block diagram of one embodiment of stages in a receiver. The stages include a differential input/single-ended output stage 502, a first single-ended (SE) input/SE output amp stage 504, and a second SE input/SE output amp stage 506. An embodiment of stage 502 has as active load output. In an embodiment, stage 502, stage 504, and stage 506 each have a gain of more than one. In an embodiment, the first SE input/SE output stage 504 has a first CMOS inverter and the second SE input/SE output stage 504 has a second CMOS inverter. In embodiments in which stage 504 contains an inverter as the amplifier then stage 504 may be referred to as a “first inverter stage” or as a “first CMOS inverter stage.” In embodiments in which stage 506 contains an inverter as the amplifier then stage 506 may be referred to as a “first inverter stage” or as a “first CMOS inverter stage.” The configuration FIG. 5 may be used within a single-ended receiver 402 or a differential receiver 404. The differential input/single-ended output stage 502 has a differential input (D1, D2) that receives V1 and V2. In one embodiment, V1 is a single-ended signal and V2 is a reference voltage (Vref). In one embodiment, V1 and V2 are two components of a differential signal. Note that the stages depicted in FIG. 5 do not necessarily reflect all of the receiver stages.

Process and/or temperature variations impact the transistors in the active load of stage 502, which impact the common mode voltage at the single-ended output of stage 502. An embodiment includes bias circuitry that generate a bias current for stage 502 that mitigates process and/or temperature variations in transistors in the active load, thereby keeping the common mode voltage at the single-ended output of stage 502 close to a target. In an embodiment, the single-ended output of stage 502 is connected to a CMOS inverter in first inverter stage 504. An embodiment includes inverter based bias circuitry having an inverter that is a replica of the CMOS inverter in stage 504. The bias current generated by this inverter-based bias circuitry ensures that the DC voltage at the single-ended output of stage 502 tracks the midpoint voltage of the voltage transfer curve (VTC) of the CMOS inverter in stage 504.

FIG. 6 depicts a block diagram of another embodiment of stages in a receiver. A fully differential (e.g., differential input/differential output) stage 602 is added to a differential input/single-ended output stage 502, a first SE input/SE output stage 504, and a second SE input/SE output stage 506. The fully differential stage 602 inputs V1 and V1 and outputs Sc and St at the differential output. The configuration FIG. 6 may be used within a single-ended receiver 402 or a differential receivers 404. In one embodiment, V1 and V2 are two components of a differential signal. In one embodiment, V1 is a single-ended signal and V2 is a reference voltage (Vref).

In an embodiment, the fully differential amplifier stage 602 has a passive load. Process and/or temperature variations could potentially impact performance of the fully differential amplifier. The common mode voltage at the differential output of the fully differential amplifier stage 602 depends on a bias current and a resistance of the passive load. An embodiment includes resistor based bias circuitry that generates a bias current for the fully differential amplifier stage 602 that has a magnitude that depends inversely on a resistance in the bias circuitry. Global process variations will impact the resistor in the passive load in a similar manner as the resistor in the bias circuitry. Moreover, temperature variations will impact the resistor in the passive load in a similar manner as the resistor in the bias circuitry. Therefore, the bias current mitigates process and/or temperature variations that may impact the fully differential amplifier 602. Consequently the common mode voltage at the differential output of stage 602 is made resistant to global process and/or temperature variations.

FIG. 7 depicts a block diagram of another embodiment of stages in a receiver. The configuration has stages also in the configuration of FIG. 6. However, there are two paths in the embodiment depicted in FIG. 7. One path is formed by differential input/single-ended output stage 502a, first SE input/SE output stage 504a, and second SE input/SE output stage 506a. The receiver has a copy of the stages 502b, 504b, 506c to form the second path. The first differential input/single-ended output stage 502a receives Sc at its D1 input and Ct at its D2 input. However, the second differential input/single-ended output stage 502b receives Sc at its D2 input and Ct at its D1 input. The first path outputs Vout and the second path outputs the compliment Vout_bar. The configuration FIG. 7 may be used within a differential receivers 404. In one embodiment, V1 and V2 are two components of a differential signal.

In some embodiments, an additional buffer stage is added at the output of the second inverter stage 506 in FIG. 6 or 7. In an embodiment, a latch or the like is added to the configuration in FIG. 7 to improve the duty cycle of the differential output signal. The latch improves the duty cycle by averaging a duty cycle of the signal in the first path with a duty cycle of the compliment signal in the second path. These and other technical benefits of embodiments of a receiver are described herein.

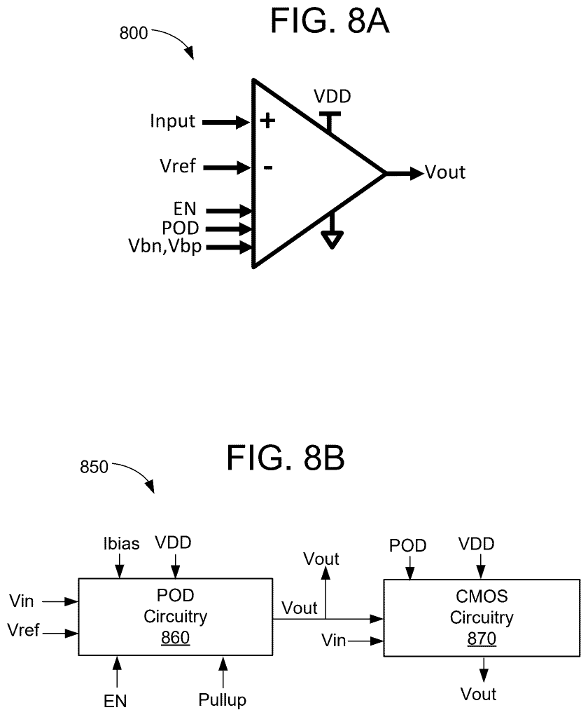

FIG. 8A is a high level diagram of an embodiment of a single-ended receiver 800. In an embodiment, the single-ended receiver supports a POD mode and a power saving mode. The receiver 800 operates as a POD (pseudo open drain) receiver in the POD mode. The power saving mode provides for a low current/low power mode. The single-ended input signal is referred to as “Input”, which is provided to one differential input (+). The reference voltage (Vref) is provided to the other differential input (−). The receiver 800 inputs an enable signal (EN). The POD signal allows selection between the POD mode and the power saving mode. Bias points may also be provided with Vbn, Vbp. The output is labeled Vout.

FIG. 8B is a block diagram of components of one embodiment of a multi-mode single-ended receiver 800. The receiver 850 has a POD circuitry 860 and CMOS circuitry 870. The POD circuitry 860 is active during an embodiment of the POD mode. The CMOS circuitry 870 is active during an embodiment of the power saving mode (also referred to as CMOS mode). The POD circuitry 860 and CMOS circuitry 870 each receive VDD, Vin. The POD circuitry 860 inputs Vin and Vref and outputs Vout. When the POD circuitry 860 is selected Vout is taken from the output of the POD circuitry 860. However, when the CMOS circuitry 870 is selected, the output is provided by the CMOS circuitry 870. Table I indicates various modes for an embodiment of receiver 850. With reference to Table I, the CMOS circuitry 870 is selected when En and POD are both 0; however the POD circuitry 860 is selected when En and POD are both 1.

TABLE I

| En | POD | Mode |
|---|---|---|
| 0 | 0 | CMOS |
| 0 | 1 | OFF |
| 1 | 0 | Illegal |
| 1 | 1 | POD |

One example use of the CMOS mode is for self-refresh. In some embodiments, the receiver 850 enters the CMOS mode in response to receiving a self-refresh (SR) command. The refresh may be used for DRAM, but is not limited to DRAM. Also, the CMOS mode has applications other than self-refresh. An example use of the OFF mode is for power down. The receiver may enter the OFF mode, for example, in response to a power down command, power save command, maximum power save command, etc. An example use of the POD mode is a normal mode of operation. For example, the POD mode may be used whenever neither the CMOS mode nor the OFF mode is in use. The POD mode will typically consume more current/power than the CMOS mode of the OFF mode. The OFF mode consumes very little current/power. The CMOS mode typically consumes far less current/power than the POD mode, but may consume more current/power than the OFF mode.

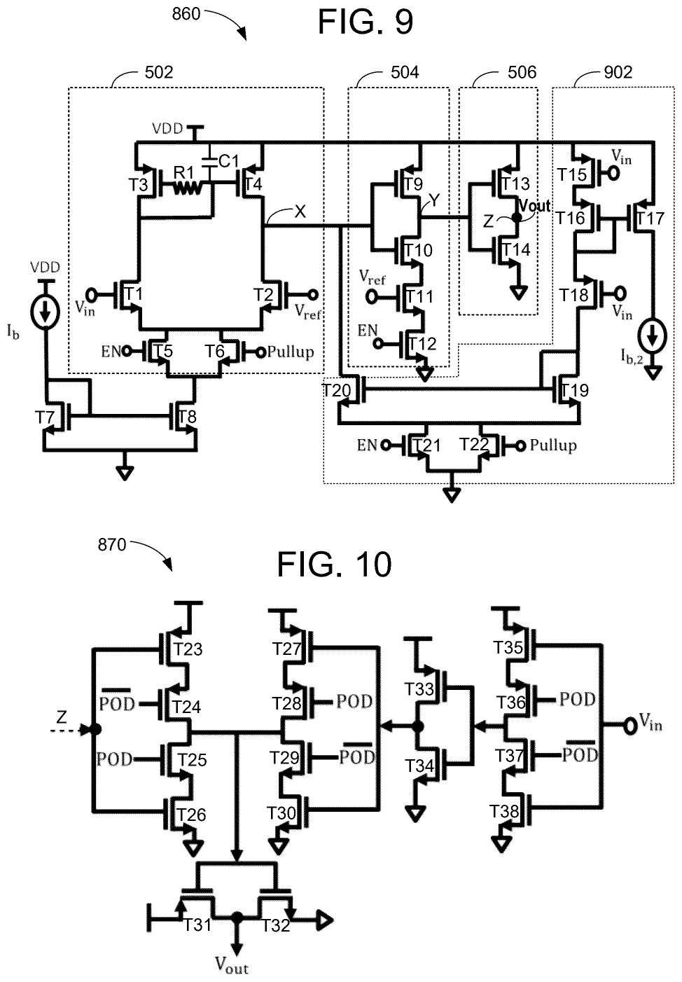

FIG. 9 is a schematic diagram of one embodiment of a receiver 860. The receiver 860 may be used within the POD circuitry 860 in FIG. 8B. However, the receiver 860 could also be used without the CMOS circuitry 870. In an embodiment, the receiver 860 is used to process a single-ended signal. The receiver 860 has multiple stages 502, 504, 506, 902. Stage 502, first inverter 504, second inverter 506 are one embodiment of the corresponding stages 502, first inverter 504, second inverter 506 in FIG. 5. The receiver 860 in FIG. 9 shows an additional stage 902, which is optional.

The differential input/single-ended output 502 stage has transistors T1, T2, T3, T4, T5, and T6. The differential input of stage 502 is the gates of T1 and T2. Transistor T1 receives input Vin at its gate. Transistor T2 receives Vref at its gate. The single-ended output of stage 502 is node X. The RC (R1, C1) helps to improve the rise time at node X, especially at low input signal swings. The gate of T5 is provided with an enable signal EN. When enable is low T5 shuts off to reduce current. The gate of T6 is provided with a pullup signal. The pullup may be implemented by connecting the gate of T6 to Vdd through a small resistor. The pullup helps T6 to be on at all times (even when enable is 0), which helps stage 502 to turn back on quickly when enable returns to high. The current source Ib and the current mirror formed by T7 and T8 provide a bias current for stage 502. Note that the bias circuitry does not require a resistor; therefore, the bias point can be precisely set with respect to process variations.

In an embodiment, T9 and T10 in first inverter stage 504 form a first CMOS inverter. In an embodiment, the first CMOS inverter is a high-skewed inverter. In a high-skewed inverter, the (W/L) ratio of PMOS to NMOS transistors are larger than un-skewed inverters. In an un-skewed inverter the (W/L) ratio (or skew ratio) of the PMOS transistor to the NMOS transistor is such that the rise and fall times are equal. Those of ordinary skill will understand that due to limitations in fabrication techniques an un-skewed inverter will not necessarily have a skew ratio of exactly 1. In an embodiment, first inverter stage 504 has a gain of more than 1. A typical range of gain in this stage is 1 to 5. Note that the output of stage 502 may have a high CM output. For example, the common mode voltage at node X may typically be greater than Vdd/2. The high-skewed amplifier helps in view of the high CM output of stage 502. Transistor T11 improves the eye width at high input signal swings by adjusting the fall time based on the input CM. The gate of T12 is provided with the enable signal EN.

In an embodiment, T13 and T14 form a second CMOS inverter. The output voltage Vout is taken at the output of the second CMOS inverter. In an embodiment, stage 506 is used to generate rail-to-rail outputs. In an embodiment, the second CMOS inverter provides gain restoration at low input signal swings. For example, if the input signal swing is low, then the gain provided by stages 502 and 502 might not provide a rail-to-rail signal. In an embodiment, Vout is rail-to-rail and may directly drive a flip-flip. Therefore, there is no need for a comparator.

The receiver 860 has an additional stage 902. Stage 902 includes T15, T16, T17, T18, T19, T20, and T21. Stage 902 is connected to node X and helps to provide a faster fall time at node X for high input signal swings. The stage 902 receives a bias from current source Ib,2. Similar to stage 502, this bias circuitry does not require a resistor; therefore, the bias point can be precisely set with respect to process variations. The bias current is mirrored to T16. The gate of T15 and T18 are both driven by Vin. Therefore, the magnitude of the current in T18 depends on Vin. This current gets mirrored by T19 to T20, which is connected to node X. The stage 902 is configured to generate a current in T20 having a magnitude that depends on a voltage magnitude of the input signal Vin. Also note that T15 helps to cut down low signal swing current leakage, especially at high temperature.

FIG. 10 is a schematic diagram of one embodiment of CMOS circuitry 870. The CMOS circuitry 870 connects to node Z of the POD circuitry 860 in FIG. 9. Therefore, node Z is connected to that gates of T23 and T26. Vin is connected to the gates of T35 and T38, which may be referred to as an input to the CMOS circuitry 870. Vout is provided between T31 and T32. The POD signal is provided to gates of T25, T28, and T36. The compliment of the POD signal (POD_bar) is provided to the gates of T24, T29, and T37. Also depicted is an inverter formed by T33 and T34, which is connected to the gates of T27 and T30.

The CMOS circuit 870 has transistors (e.g., T33-T38) that provide a low current path between the input (at gates of T35 and 38) and the output of the CMOS circuit. Transistors T23-T30 form a MUX that is controlled by the POD signal. When in the POD mode, the MUX provides the signal from node Z to the output of the CMOS circuit 870. When in the CMOS mode, the MUX selects the low current path from the input (gates of T35 and 38) of the CMOS circuit 870. Therefore, the CMOS circuit 870 provides for either a POD mode or a low current/power mode.

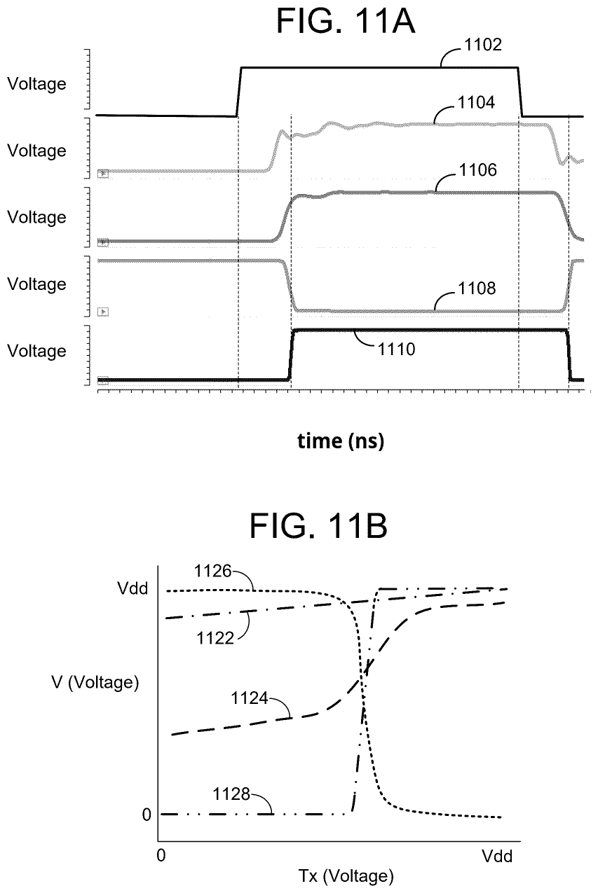

FIG. 11A is a graph of voltage waveforms versus time for the channel and various nodes in an embodiment of a receiver. FIG. 11A is for a small swing example. The graph will be discussed with reference to nodes in receiver 860 in FIG. 9. Waveform 1102 is the voltage at the transmitter. Waveform 1104 is the channel voltage. Waveform 1106 is the voltage at node X in receiver 860 in FIG. 9. Waveform 1108 is the voltage at node Y in receiver 860. Waveform 1110 is the voltage at node Z (Vout) in receiver 860. Each stage provides a cleaner signal that more closely resembles the transmitted signal. The gain provided by each stage is not explicitly depicted in FIG. 11A. However, each stage may have a gain greater than 1. It will be understood by those of ordinary skill in the art that there will be a limit to the minimum and maximum voltages of the waveforms (e.g., 0V to Vdd). Therefore, some signals may already be at the minimum or maximum voltage prior to the final stage. Therefore, it is not required that all stages will amplify all signals.

FIG. 11B is a DC voltage for a small swing example. Waveform 1122 is for the channel (e.g., the voltage Vin). Waveform 1124 is the voltage at node X in receiver 860 of FIG. 9. Waveform 1124 shows that there has been substantial improvement of the signal swing. Waveform 1126 is the voltage at node Y in receiver 860. The gain of stage 504 results in further improvement of the signal swing. Waveform 1128 is the voltage at node Z (Vout) in receiver 860. The gain of stage 506 results in further improvement of the signal swing, resulting in a fully rail-to-rail (0V to Vdd) signal swing.

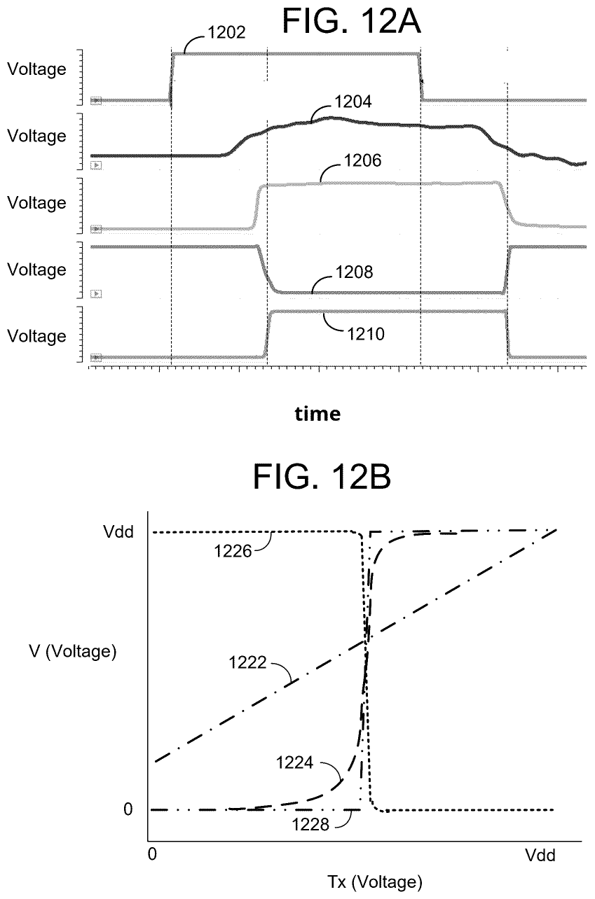

FIG. 12A is another graph of voltage waveforms versus time for the channel and various nodes in an embodiment of a receiver. FIG. 12A is for a large swing example. Waveform 1202 is the voltage at the transmitter. Waveform 1204 is the channel voltage. Waveform 1206 is the voltage at node X in receiver 860. Waveform 1208 is the voltage at node Y in receiver 860. Waveform 1210 is the voltage at node Z (Vout) in receiver 860. Each stage provides a cleaner signal that more closely resembles the transmitted signal.

FIG. 12B is a DC voltage the corresponds to the graph in FIG. 12A for the large swing example. Waveform 1222 is for the channel (e.g., Vin). Waveform 1224 is the voltage at node X in receiver 860. Waveform 1224 shows that there has been substantial improvement of the signal swing due to stage 502. Waveform 1226 is the voltage at node Y in receiver 860. Waveform 1226 shows that the gain of stage 504 results in further improvement of the signal swing. Waveform 1228 is the voltage at node Z (Vout) in receiver 860.

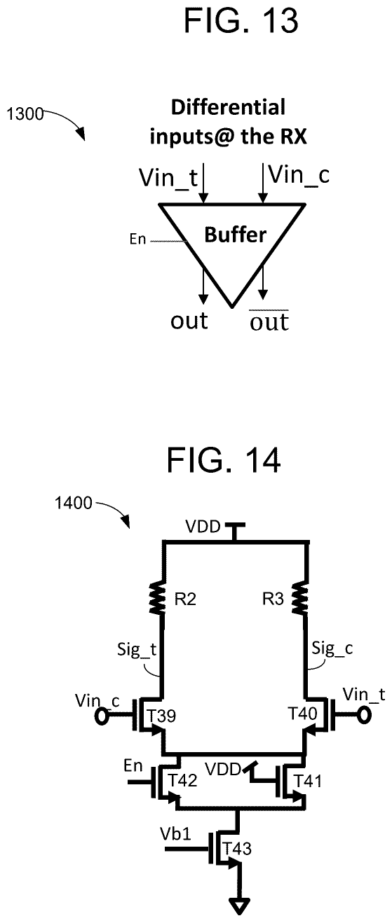

FIG. 13 is a high level diagram of a fully differential receiver 1300. The fully differential receiver 1300 has a differential input that inputs a differential signal: Vin_t and Vin_c. The fully differential receiver 1300 has a differential output that inputs a differential output signal: out and out_bar. The differential receiver 1300 has an enable (EN).

An embodiment of a differential receiver has a number of stages. Referring back to the block diagram in FIG. 6, and embodiment of a differential receiver has a number of stages (note that the configuration of FIG. 6 may also be used for single-ended signals). FIG. 14 is a schematic diagram of one embodiment of a fully differential amplifier stage 1400, which may be used for fully differential amplifier stage 602 in either FIG. 6 or 7, but is not limited thereto. The gate of T39, which is one node of the differential input, receives Vin_c. The gate of T40, which is the other node of the differential input, receives Vin_t. The differential output provides Sig_c and Sig_t. Note that Vin_c and Vin_t are typically compliments of each other for a differential signal. Stage 1400 has an active load (R2, R3). The two resistors R2, R3 are matched in resistance. An enable signal (EN) is provided to the gate of T42. VDD is applied to the gate of T41. Transistor T41 allows for a small current to flow in the stage 1400 even when the stage 1400 is not enabled (e.g., T42 is off). This small current allows stage 1400 to be turned back on quickly when enable (EN) is brought high. A bias voltage Vb1 is provided to the gate of T43. Bias circuitry that provides Vb1 for stage 1400 will be discussed below.

In an embodiment, the gain of the stage 1400 is between about 2 to 3; however, a smaller or larger gain could be used. The gain of stage 1400 may be used to increase the signal swing to a target minimum, such as a 150 mV, even if there is a relatively small input signal swing. Increasing the signal swing to a target minimum helps to provide good operation even for a very low signal swing. The target minimum can depend on the application. For example if the input signal swing at the differential input (Vin_c and Vin_t at gates of T39 and T40, respectively) is 50 mV, then a gain of 3 results in a 150 mV voltage swing at the differential input (Sig_c, Sig_t). However, this is just one example for illustrative purpose.

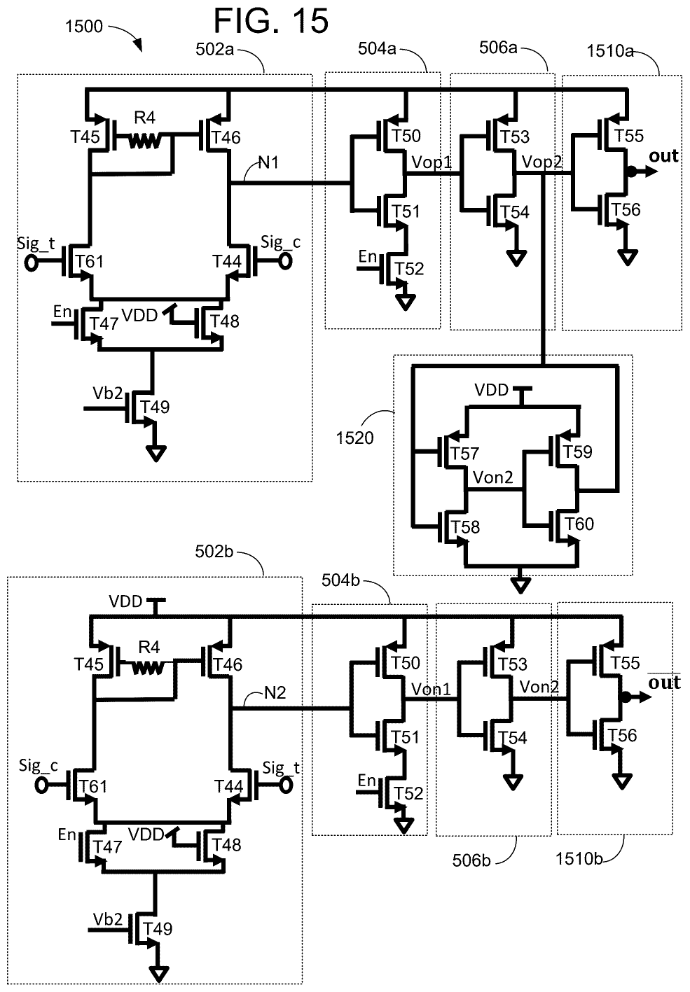

FIG. 15 is a schematic diagram of circuitry 1500 that may be used in combination with the stage 1400 depicted in FIG. 14. The circuitry 1500 may be used for two complimentary paths of an embodiment of a differential receiver. In general, each path has four stages. One path has stages 502a, 504a, 506a, and 1510a. The other path has stages 502b, 504b, 506b, and 1510b. The corresponding stages in each path are copies (or replicas) of each other; therefore, the same reference numerals are used to refer to circuit elements that copies of each other. Note that stages 502a, 504a, 506a, 502b, 504b, and 506b may be used in an embodiment of FIG. 7 (with, for example, fully differential amp 1400 in FIG. 14 being used for stage 602). In another embodiment, stages 502a, 504a, and 506a may be used in an embodiment of FIG. 6 (with, for example, fully differential amp 1400 in FIG. 14 being used for stage 602). There is also a data latch 1520 that is connected to both paths.

The first stage 502 of each path has a differential input (gates of T61, T44). These differential inputs receive the output (Sig_t, Sig_c) from fully differential stage 1400 (depicted in FIG. 14). The gate of T61 in stage 502a is connected to Sig_t, whereas the gate of T61 in stage 502b is connected to Sig_c. The gate of T44 in stage 502a is connected to Sig_c, whereas the gate of T44 in stage 502b is connected to Sig_t. Thus, it may be stated that the differential input of stage 502b receives the compliment of the signal received by the differential input of stage 502a. Stage 1510a provides an output voltage (out), whereas stage 1510b provides the compliment of the output voltage (out_bar).

The single-ended output of stage 502a is node N1. The single-ended output of stage 502b is node N2. Stages 502a, 502b are similar to stage 502 in FIG. 9; however, stages 502a and 502b are biased differently than stage 502 in FIG. 9. Resistor R4 is connected between the gates of T45 and T46. R4 helps to improve the rise time at node N1 (or N2), especially at low input signal swings. R4 has similar technical benefits as R1 in stage 502 in FIG. 9, which has been discussed above. The gate of T47 is provided with an enable signal EN. VDD is provided to the gate of T48. Transistor T48 allows for a small current to flow in the stage 502a, 502b even when the stage is not enabled (e.g., T47 off). A bias voltage Vb2 is provided to the gate of T49. Bias circuitry that provides Vb2 for stages 502a, 502b will be discussed below.

In an embodiment, T50 and T51 form a CMOS inverter in each respective stage 504a, 504b. In an embodiment, stages 504a and 504b are each high-skewed inverters. In an embodiment, stages 504a and 504b each have a gain of more than 1. A typical gain of 1 to 5 is expected at this stage. The input of stage 504a is connected to the output of stage 502a. The input of stage 504b is connected to the output of stage 502b. The voltage at the output of stage 504a is referred to as Vop1. The voltage at the output of stage 504b is referred to as Von1. The gate of T52 is provided with an enable signal EN.

In an embodiment, T53 and T54 form a CMOS inverter in each respective stage 506a, 506b. The input of stage 506a is connected to the output of stage 504a. The input of stage 506b is connected to the output of stage 504b. In an embodiment, stages 506a and 506b each have a gain of more than 1. The voltage at the output of stage 506a is referred to as Vop2. The voltage at the output of stage 506b is referred to as Von2. These stages 506a, 506b generate rail-to-rail output.

In an embodiment, T55 and T56 form a buffer in each respective stage 1510a, 1510b. The input of stage 1510a is connected to the output of stage 506a. The input of stage 1510b is connected to the output of stage 506b. The voltage at the output of stage 1510a is referred to as out. The voltage at the output of stage 1510b is referred to as out_bar. The output stages 1510a, 1510b provide buffering to drive a capacitive load.

The data latch 1520 has T57, T58, T59, and T60. The data latch 1520 serves to average the duty cycle of Vop2 and Von2. Therefore, the data latch 1520 reduces the spread of duty cycle variations by averaging the duty cycle from the top path and the bottom path.

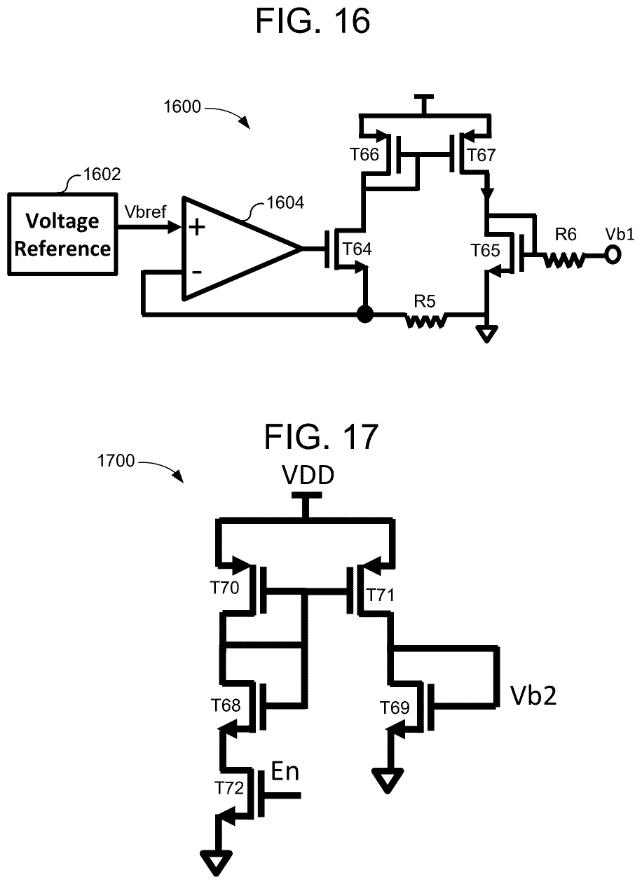

FIG. 16 is a schematic diagram of one embodiment of a biasing circuit 1600 for an embodiment of a fully differential amplifier stage. The biasing circuit 1600 may be used to provide a bias voltage vb1 for fully differential amplifier stage 1400 (see FIG. 14), but is not limited thereto. Moreover, fully differential stage 1400 could be biased by circuitry other than biasing circuit 1600. The biasing circuit 1600 is a resistor based biasing circuit. In an embodiment, the biasing circuit 1600 sets the output common mode of fully differential stage 1400 (see FIG. 14) to be process independent. The biasing circuit 1600 has a voltage reference generator 1602, an operational amplifier 1604, transistors T64, T65, T66, T67, R5 and R6. The voltage reference 1602 provides a bias reference voltage Vbref to the non-inverting input of the operational amplifier 1604. The output of the operational amplifier 1604 drives the gate of T64. The current through T64 may be Vbref/R5. As an example, Vbref may be about 0.4V; however, Vbref may be higher or lower. As one example, R5 may be about 24K Ohm; however, R5 may have a higher or lower resistance. The current through T64 is mirrored by T66 to T67. Resistor R6 may be connected to the gate of T43 (see FIG. 14) to provide the bias voltage Vb1 to fully differential amplifier stage 1400. Therefore, T43 may provide a bias current for fully differential amplifier stage 1400. As noted, the biasing circuit 1600 is a resistor based biasing circuit. The biasing current Ibais1 depends on the inverse of the magnitude of the resistance of R5. Using such a resistor based biasing circuit mitigates process and/or temperature issues in fully differential amplifier stage 1400. The biasing current (Ibais1) will set the common mode voltage at the output of fully differential amplifier stage 1400. The common mode voltage will be (VDD−R2)*Ibais1. Therefore, the common mode voltage depends on the resistance of R2. Due to process variations and temperature variations the resistance of R2 could have a significant deviation from a target resistance. For example, the resistance of R2 could deviate from a target resistance by up to 20 percent or even more. However, the resistance of R5 should also deviate by a similar percentage due to global process variations and the same temperature variations. Thus, the resistor based biasing circuit mitigates process and/or temperature issues in fully differential amplifier stage 1400.

FIG. 17 is a schematic diagram of one embodiment of a biasing circuit 1700 for an embodiment of a differential input/single-ended output stage such as stage 502a or 502b in FIG. 15. Biasing circuit 1700 is an inverter based biasing circuit. In an embodiment, transistors T70, T68, and T72 form a replica of the inverter in inverter stage 504a or 504b in FIG. 15. Thus, in an embodiment, transistors T70, T68, and T72 are a replica of T50, T51, and T52 (see stage 504a or 504b in FIG. 15). The gate of T69 may be connected to the gate of T49 (see stage 502a or 502b in FIG. 15) to bias stage 502a or 502b. Therefore, T49 may provide a bias current for stage 502a or 502b. The inverter based biasing circuit helps to mitigate process and/or temperature issues with the common mode voltage at node N1 in stage 502a or N2 in stage 502b (see FIG. 15). The common mode voltages at N1 and N2 depend on T45, T46 and the bias current to stages 502a, 502b, respectively. Process and/or temperature variations impact T45 and T46. Therefore, the common mode voltages at N1 and N2 may change with process and/or temperature variations. The bias current generated by biasing circuit 1700 mitigates process and/or temperature variations in T45 and T46, thereby keeping the common mode voltages at N1 and N2 close to a target voltage. This bias current ensures that the DC voltage at N1 and N2 tracks the midpoint voltage of the voltage transfer curve (VTC) of the inverter in stage 504a or 504b (see FIG. 15).

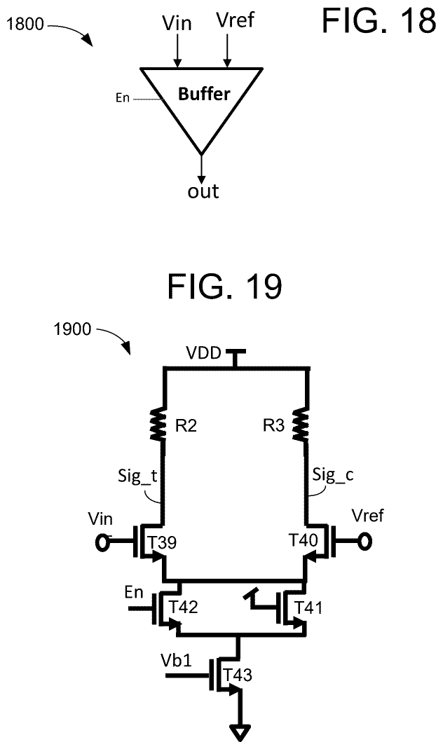

As noted herein, in some embodiments the fully differential amplifier stage 1400 is used with other circuitry to process a differential signal. However, in some embodiments, the fully differential stage 1400 is used with other circuitry to process a single-ended signal. FIG. 18 is a high level schematic of a single-ended receiver 1800. The single-ended receiver 1800 receives as inputs the single-ended signal Vin and a reference voltage Vref. The single-ended receiver 1800 also receives an enable signal EN. The single-ended receiver 1800 provides a single-ended output signal (out).

FIG. 19 is a schematic diagram of one embodiment of a differential input/differential output amplifier stage 1900, which may be used as a first stage of a single-ended receiver such as, but not limited to receiver 1800. The stage 1900 may have similar components as the fully differential amplifier stage 1400 in FIG. 14; therefore, the same reference numerals are used in FIG. 19 for similar components. Stage 1900 is operated differently from fully differential amplifier stage 1400 in that T39 receives the single-ended input signal Vin and T40 receives the reference voltage Vref. In addition to stage 1900, an embodiment of the single-ended receiver has stages 502a, 504a, 506a, and 1510a as depicted in FIG. 15. However, the data latch 1520 and the lower path (stages 502b, 504b, 506c, and 1510b) are not used in the single-ended receiver. Note that the block diagram in FIG. 6 shows stages that may be used to process a single-ended signal. In an embodiment, the fully differential amplifier stage 1900 in FIG. 19 is used for stage 602 in FIG. 6 and stages 502a, 504a, and 506a from FIG. 15 are used for stages 502, 504, 506, respectively in FIG. 6. Buffer stage 1510a may also be added to such a configuration.

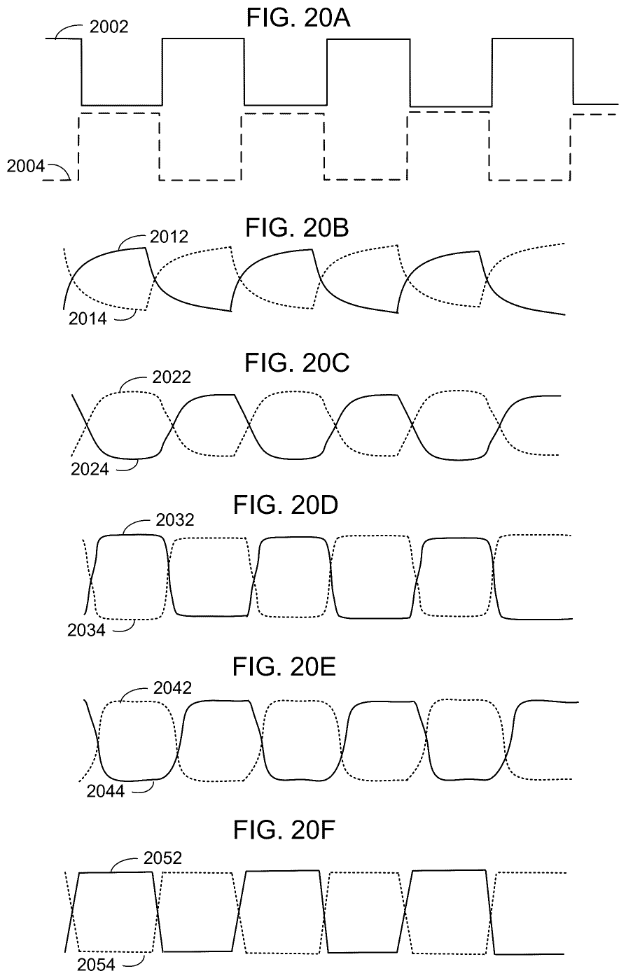

FIGS. 20A-20F depict waveforms of voltage signals at various points in an embodiment of a differential receiver such as a receiver having a fully differential amplifier stage 1400 and the circuitry 1500 depicted in FIG. 15. FIG. 20A shows waveform 2002 for Vin_t and waveform 2004 for Vin_c. FIG. 20B shows waveform 2012 for Sig_c and waveform 2014 for Sig_t. FIG. 20C shows waveform 2022 for the signal an N1 and waveform 2024 for the signal at N2. FIG. 20D shows waveform 2032 for the signal Vop1 and waveform 2034 for the signal Von1. FIG. 20E shows waveform 2042 for the signal Vop2 and waveform 2044 for the signal Von2. FIG. 20F shows waveform 2052 for the signal out and waveform 2054 for the signal out_bar.

Referring back to FIG. 8B, some embodiments have POD circuitry 860 and CMOS circuitry 870. FIG. 9 depicts one embodiment of POD circuitry 860 and FIG. 10 depicts one embodiment of CMOS circuitry 870. Receivers having a fully differential input stage such as stage 1400 in FIG. 14 may also be used in an embodiment of POD circuitry 860 that is used in combination with CMOS circuitry 870. Stage 1400 in FIG. 14 and circuitry 1500 in FIG. 15 may be used in one embodiment of POD circuitry 860. Such and embodiment of POD circuitry 860 may be used with CMOS circuitry 870 depicted in FIG. 10. However, rather than connecting the CMOS circuitry 870 to node Z (see FIG. 9), the CMOS circuitry 870 may be connected to out or out_bar in FIG. 15. In a single-ended embodiment, the stage 1900 in FIG. 19 and stages 502a, 504a, 506a, and 1510a in FIG. 15 are used in one embodiment of POD circuitry 860 in combination with CMOS circuitry 870 depicted in FIG. 10.

In view of the foregoing, it can be seen that a first embodiment includes a receiver comprising a first stage comprising a differential input and a single-ended output having an active load. The differential input is configured to receive an input signal. The first stage configured to amplify the input signal and provide the amplified input signal to the single-ended output. The receiver includes a second stage comprising an input coupled to the single-ended output of the first stage. The second stage configured to further amplify the input signal and provide the further amplified input signal at a single-ended output of the second stage.

In a further embodiment, the receiver circuit further includes a third stage comprising a fully differential amplifier having a differential input and differential output. The differential output of the third stage is coupled to the differential input of the first stage. The third stage is configured to receive the input signal at the differential input, amplify the input signal, and provide the amplified input signal to the differential output. The input signal received at the differential input of the first stage is the amplified input signal from the third stage.

In a further embodiment, the receiver circuit further includes a biasing circuit configured to provide a bias current for the third stage. The biasing circuit comprises a first resistor, wherein a magnitude of the bias current depends inversely on resistance of the first resistor. The differential output of the third stage has a passive load comprising a second resistor. A common mode voltage at the differential output of the third stage depends on both the bias current and a resistance of the second resistor. The bias current mitigates process and/or temperature variations that may impact the fully differential amplifier. Consequently the common mode voltage at the differential output is made resistant to global process and/or temperature variations.

In a further embodiment, the receiver circuit further includes a copy (or replica) of the first stage and a copy (or replica) of the second stage. The differential input of the copy of first stage is coupled to the differential output of the third stage to receive a compliment of the input signal. A first path that includes the first stage and the second stage processes the input signal from the third stage to generate an output voltage signal. A second path that includes the copy of the first stage and the copy of the second stage processes the compliment of the input signal from the third stage to generate a compliment of the output voltage signal.

In a further embodiment, the receiver circuit further includes a latch coupled the first path and to the second path. The latch is configured to average a first duty cycle of the input signal on the first path with a second duty cycle of the compliment of the input signal on the second path.

In a further embodiment, the receiver circuit further includes a biasing circuit configured to provide a bias for the first stage. The biasing circuit comprises an inverter that is a replica of an inverter in the second stage. The single-ended output of the first stage comprises an active load having a transistor. The bias current generated by this biasing circuit mitigates process and/or temperature variations in the transistor in the active load, thereby keeping the common mode voltages at the single-ended output of the first stage close to a target voltage. In an embodiment, this bias current ensures that the DC voltage at the single-ended output of the first stage tracks the midpoint voltage of the voltage transfer curve (VTC) of the inverter in the second stage.

In a further embodiment, the second stage comprises a first inverter. The first inverter being a high-skewed inverter. The receiver further comprising a stage comprising a second inverter having an input coupled to the output of the first inverter. The second inverter is configured to further amplify the input signal and provide the further amplified input signal at an output of the second inverter.

In a further embodiment, the receiver circuit further includes a stage comprising a buffer having an input coupled to the output of the second inverter and an output. The buffer stage is configured to provide buffering to drive a capacitive load.

In a further embodiment, the receiver circuit further includes a CMOS circuit having a first input coupled to the output of the stage having the second inverter, a second input configured to receive the input signal, and an output. The CMOS circuit comprises transistors configured to provide a low current path between the second input and the output of the CMOS circuit. The CMOS circuit comprises a MUX configured to provide the output from the third stage to the output of the CMOS circuit when the MUX is operated in a first mode. The MUX is configured to provide the input signal from the second input of the CMOS circuit to the output of the CMOS circuit when the MUX is operated in second mode.

In a further embodiment, the first stage further comprises a first transistor coupled to a first side of the differential input of the first stage. The first transistor is configured to enable/disable the first stage responsive to an enable signal at a gate of the first transistor. The first stage further comprises second transistor coupled to a second side of the differential input of the first stage. A gate of the second transistor is coupled to a voltage to allow for a small current in the second transistor when the first transistor is off to thereby disable the first stage.

In a further embodiment, the first stage active load comprises a first transistor coupled between a voltage source and a first input of the differential input of the first stage, a second transistor coupled between the voltage source and a second input of the differential input of the first stage, and a resistor coupled between a first gate of the first transistor and a second gate of the second transistor. In an embodiment, the resistor helps to improve the rise time at the single-ended output of the first stage, especially at low input signal swings.

In a further embodiment, the first stage further comprises a first transistor coupled to a first side of the differential input of the first stage. The first transistor is configured to enable/disable the first stage responsive to an enable signal at a gate of the first transistor. The first stage further comprises a second transistor coupled to a second side of the differential input of the first stage. A gate of the second transistor is coupled to a voltage to allow for a small current in the second transistor when the first transistor is off to thereby disable the first stage.

In a further embodiment, the receiver circuit further includes a fourth stage having a transistor coupled to the output of the first stage. The fourth stage is configured to generate a current in the transistor having a magnitude that depends on a voltage magnitude of the input signal.

An embodiment includes a method of processing a signal with a receiver. The method comprises receiving a first voltage signal at a first input of a differential input of a first stage of the receiver while receiving a second voltage signal at a second input of the differential input of the first stage. The method comprises amplifying a difference between the first voltage signal and the second voltage signal to provide a first stage voltage signal to an active load single-ended output of the first stage. The method comprises further amplifying the first stage voltage signal with a first CMOS inverter in a second stage of the receiver to provide a second stage voltage signal to an output of the first CMOS inverter. The method comprises further amplifying the second stage voltage signal with a second CMOS inverter in a third stage of the receiver to provide a third stage voltage signal to an output of the second CMOS inverter.

An embodiment includes a differential receiver circuit comprising a fully differential amplifier having a differential input and differential output. The fully differential amplifier is configured to amplify a differential input signal at the differential output and provide the amplified differential input signal to the differential output as a first voltage signal at a first node and a second voltage signal at a second node. The differential receiver circuit comprises first circuitry having a differential input and a first single-ended output. The differential input of the first circuitry is coupled to the differential output of the fully differential amplifier. The first circuitry comprises electronic components configured to amplify the first voltage signal minus the second voltage signal and to provide a first output voltage signal at the first single-ended output. The differential receiver circuit comprises second circuitry having a differential input and a second single-ended output, the differential input of the second circuitry coupled to the differential output of the fully differential amplifier. The second circuitry comprising electronic components configured to amplify the second voltage signal minus the first voltage signal and to provide a second output voltage signal at the second single-ended output, wherein the difference between the first output voltage signal and the second output voltage signal is a differential output signal.

For purposes of this document, the term “electronic component” includes both active and passive components. Examples of electronic components include, but are not limited to, transistors (e.g., FET, BJT, etc.), diodes, resistors, capacitors, and inductors.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. A receiver comprising:
a first stage comprising a differential input and a single-ended output having an active load, the differential input configured to receive an input signal, the first stage configured to amplify the input signal and provide the amplified input signal to the single-ended output; and
a second stage comprising an input coupled to the single-ended output of the first stage, the second stage configured to further amplify the input signal and provide the further amplified input signal at a single-ended output of the second stage.

2. The receiver of claim 1, further comprising:
a third stage comprising a fully differential amplifier having a differential input and differential output, the differential output of the third stage coupled to the differential input of the first stage, the third stage configured to receive the input signal at the differential input, amplify the input signal, and provide the amplified input signal to the differential output, wherein the input signal received at the differential input of the first stage is the amplified input signal from the third stage.

3. The receiver of claim 2, further comprising:
a biasing circuit configured to provide a bias current for the third stage, the biasing circuit comprising a first resistor, wherein a magnitude of the bias current depends inversely on resistance of the first resistor, wherein the differential output of the third stage has a passive load comprising a second resistor, wherein a common mode voltage at the differential output of the third stage depends on both the bias current and a resistance of the second resistor.

4. The receiver of claim 2, further comprising:
a copy of the first stage and a copy of the second stage, wherein the differential input of the copy of first stage is coupled to the differential output of the third stage to receive a compliment of the input signal;
wherein a first path comprising the first stage and the second stage processes the input signal from the third stage to generate an output voltage signal; and
wherein a second path comprising the copy of the first stage and the copy of the second stage processes the compliment of the input signal from the third stage to generate a compliment of the output voltage signal.

5. The receiver of claim 4, further comprising:
a latch coupled the first path and to the second path, the latch configured to average a first duty cycle of the input signal on the first path with a second duty cycle of the compliment of the input signal on the second path.

6. The receiver of claim 1, further comprising a biasing circuit configured to provide a bias for the first stage, the biasing circuit comprising an inverter that is a replica of an inverter in the second stage.

7. The receiver of claim 1, wherein the second stage comprises a first inverter, the first inverter being a high-skewed inverter, and further comprising a third stage comprising a second inverter having an input coupled to the output of the first inverter, the second inverter configured to further amplify the input signal and provide the further amplified input signal at an output of the second inverter.

8. The receiver of claim 7, further comprising:
a CMOS circuit having a first input coupled to the output of the third stage, a second input configured to receive the input signal, and an output, wherein the CMOS circuit comprises transistors configured to provide a low current path between the second input and the output of the CMOS circuit, the CMOS circuit comprising a MUX configured to provide the output from the third stage to the output of the CMOS circuit when the MUX is operated in a first mode, the MUX configured to provide the input signal from the second input of the CMOS circuit to the output of the CMOS circuit when the MUX is operated in second mode.

9. The receiver of claim 7, further comprising:
a fourth stage having a transistor coupled to the output of the first stage, the fourth stage configured to generate a current in the transistor having a magnitude that depends on a voltage magnitude of the input signal.

10. The receiver of claim 7, further comprising:
a fourth stage comprising a buffer having an input coupled to the output of the second inverter and an output, the fourth stage configured to provide buffering to drive a capacitive load.

11. The receiver of claim 1, wherein the first stage further comprises:
a first transistor coupled to a first side of the differential input of the first stage, the first transistor configured to enable/disable the first stage responsive to an enable signal at a gate of the first transistor; and
a second transistor coupled to a second side of the differential input of the first stage, a gate of the second transistor coupled to a voltage to allow for a small current in the second transistor when the first transistor is off to thereby disable the first stage.

12. The receiver of claim 1, wherein the active load of the first stage comprises:
a first transistor coupled between a voltage source and a first input of the differential input of the first stage;
a second transistor coupled between the voltage source and a second input of the differential input of the first stage; and
a resistor coupled between a first gate of the first transistor and a second gate of the second transistor.

13. A method of processing a signal with a receiver, the method comprising:
receiving a first voltage signal at a first input of a differential input of a first stage of the receiver while receiving a second voltage signal at a second input of the differential input of the first stage;
amplifying a difference between the first voltage signal and the second voltage signal to provide a first stage voltage signal to an active load single-ended output of the first stage;
further amplifying the first stage voltage signal with a first CMOS inverter in a second stage of the receiver to provide a second stage voltage signal to an output of the first CMOS inverter; and
further amplifying the second stage voltage signal with a second CMOS inverter in a third stage of the receiver to provide a third stage voltage signal to an output of the second CMOS inverter.

14. The method of claim 13, further comprising:
receiving a first input voltage signal at a first input of a differential input of a fourth stage of the receiver while receiving a second input voltage signal at a second input of the differential input of the fourth stage;
amplifying a difference between the first input voltage signal and the second input voltage signal to provide a differential fourth stage voltage signal to a passive load differential output of the fourth stage; and
providing the differential fourth stage voltage signal to the first stage as the first voltage signal and the second voltage signal.

15. The method of claim 14, wherein the first stage, the second stage and the third stage comprise a first path that processes the differential fourth stage voltage signal, and further comprising:
providing a compliment of the differential fourth stage voltage signal to a second path that comprising a replica of the first stage, the second stage and the third stage; and
forming a final differential output signal from a first single-ended output signal of the first path and a second single-ended output signal of the second path, the second single-ended output signal being a compliment of the first single-ended output signal.

16. A differential receiver circuit comprising:
a fully differential amplifier having a differential input and differential output, the fully differential amplifier configured to amplify a differential input signal at the differential output and provide the amplified differential input signal to the differential output as a first voltage signal at a first node and a second voltage signal at a second node;
first circuitry having a differential input and a first single-ended output, the differential input of the first circuitry coupled to the differential output of the fully differential amplifier, the first circuitry comprising electronic components configured to amplify the first voltage signal minus the second voltage signal and to provide a first output voltage signal at the first single-ended output; and
second circuitry having a differential input and a second single-ended output, the differential input of the second circuitry coupled to the differential output of the fully differential amplifier, the second circuitry comprising electronic components configured to amplify the second voltage signal minus the first voltage signal and to provide a second output voltage signal at the second single-ended output, wherein the difference between the first output voltage signal and the second output voltage signal is a differential output signal.

17. The differential receiver circuit of claim 16, further comprising:
a biasing circuit configured to provide a bias current for the fully differential amplifier, the biasing circuit comprising a first resistor, wherein a magnitude of the bias current depends on resistance of the first resistor, wherein the differential output of the fully differential amplifier has a passive load comprising a second resistor, wherein a common mode voltage at the differential output of the fully differential amplifier depends on both the bias current and a resistance of the second resistor.

18. The differential receiver circuit of claim 16, wherein the first circuitry comprises:
a first stage comprising the differential input of the first circuitry and a single-ended output, the single-ended output having an active load having a transistor, the differential input of the first circuitry configured to receive the first voltage signal minus and the second voltage signal, the first stage configured to amplify the difference between the first voltage signal and the second voltage signal and to provide the amplified difference at the single-ended output; and
a second stage comprising a CMOS inverter having an input coupled to the single-ended output of the first stage, the CMOS inverter having a gain greater than 1, the CMOS inverter being a high skewed inverter.

19. The differential receiver circuit of claim 18, further comprising:
a biasing circuit configured to provide a bias for the first circuitry, the biasing circuit comprising an inverter that is a replica of the CMOS inverter.

20. The differential receiver circuit of claim 16, further comprising:
a latch coupled between the first circuitry and the second circuitry, the latch configured to receive a first voltage signal having a first duty cycle from the first circuitry and to receive a second voltage signal having a second duty cycle from the second circuit, the latch configured to average the first duty cycle with the second duty cycle.
